(19) United States
(12) Patent Application Publication
(10) Pub. No.: US 2026/0205253 A1
(43) Pub. Date: Jul. 16, 2026

(54) DEVICE AND METHOD OF SIMULTANEOUS BI-DIRECTIONAL COMMUNICATION

(71) Applicant: Taiwan Semiconductor Manufacturing Company, Ltd., Hsinchu (TW)

(72) Inventors: Shu-Chun YANG, Hsinchu (TW); Wei Chih CHEN, Hsinchu (TW)

(73) Assignee: Taiwan Semiconductor Manufacturing Company, Ltd., Hsinchu (TW)

(21) Appl. No.: 19/202,557

(22) Filed: May 8, 2025

Related U.S. Application Data
(60) Provisional application No. 63/744,634, filed on Jan. 13, 2025.

(51) Int. Cl. H04L 5/14; H03K 3/037; H04L 7/00

(52) U.S. Cl. CPC H04L 5/1461; H03K 3/037; H04L 7/0008; H04L 7/0037

(57) ABSTRACT

An embodiment communication system includes a data lane based on a first conductive structure, a first transmission circuitry including a first output driver configured to output a first component signal to a first terminal of the data lane, and a second transmission circuitry including a second output driver configured to output a second component signal to a second terminal of the data lane. The first component signal is based on first data, and the second component signal is based on second data. The first output driver is configured to be energized by a first supply voltage. The second output driver is configured to be energized by a second supply voltage. A second supply voltage level of the second supply voltage is n times a first supply voltage level of the first supply voltage, and n is a real number equal to or greater than 1.5.

### PRIORITY CLAIM AND CROSS-REFERENCE

This patent application claims the benefits of U.S. Provisional Patent Application No. 63/744,634 filed on Jan. 13, 2025, the entire disclosure of which is hereby incorporated by reference.

### BACKGROUND

Digital electronic devices based on semiconductor integrated circuits, such as laptop computers, mobile phones, digital cameras, wearable devices, etc., are designed to have more powerful functions to adapt to various applications in the modern digital world. However, with the trend of semiconductor manufacturing, digital electronic devices are becoming smaller and lighter, as well as having improved functionality and higher performance. Semiconductor integrated circuits may be packaged into 2.5-dimensional (2.5D) or three-dimensional (3D) integrated circuits, where several dies may be arranged within the same integrated circuit package. Contact elements, interposer layers, or redistribution layers (RDLs) are used to make connections between different dies. In some designs, one die may need to communicate with one or more other dies within the same IC package.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a high-level block diagram of a communication system that includes two semiconductor dies, in accordance with some embodiments.

FIG. 2A is a functional block diagram of a first portion of a communication system, in accordance with some embodiments.

FIG. 2B is a signal diagram of voltage levels of various signal components in the communication system in FIG. 2A, in accordance with some embodiments.

FIGS. 3A-3C are circuit diagrams of flip-flop circuits in a data extraction circuitry of side A die in FIG. 2A, in accordance with some embodiments.

FIGS. 4A-4C are circuit diagrams of flip-flop circuits in a data extraction circuitry of side B die in FIG. 2A, in accordance with some embodiments.

FIGS. 5A-5C are circuit diagrams of decoding circuits in a receiving circuitry, in accordance with some embodiments.

FIG. 6A is a circuit diagram of a second portion of the communication system in FIG. 2A, in accordance with some embodiments.

FIG. 6B is a circuit diagram of a third portion of the communication system in FIG. 2A, in accordance with some embodiments.

FIGS. 7A-7B are signal timing diagrams of various signals at the interface circuitry of the side A die in the communication system in FIGS. 2A, 6A, and 6B, in accordance with some embodiments.

FIGS. 8A-8B are signal timing diagrams of various signals at the interface circuitry of the side B die in the communication system in FIGS. 2A, 6A, and 6B, in accordance with some embodiments.

FIG. 9 is a flowchart of a communication method, in accordance with some embodiments.

FIG. 10 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “including” or “consisting of.” In this disclosure, the phrase “one of A, B, and C” means “A, B, and/or C” (A, B, C, A and B, A and C, B and C, or A, B and C), and does not mean one element from A, one element from B, and one element from C, unless otherwise described.

In some embodiments, a simultaneous bi-directional communication system is based on separate voltage levels for inbound and outbound data signals. For example, one side of the communication system is configured to transmit data on a data lane based on a first supply voltage level (e.g., VDDA), and another side of the communication system is configured to transmit data on the same data lane based on a second supply voltage level (e.g., VDDB), where VDDB is n times VDDA, and n is equal to or greater than 1.5. In some embodiments, based on the separate voltage levels used by different sides of the communication system to transmit data signals, the incoming data can be isolated and extracted. According to one or more embodiments of the present disclosure, additional duplicate transmitters to cancel out the outbound signal are omitted, and the power consumption of the integrated circuit is therefore reduced compared to other applications with such duplicate transmitters.

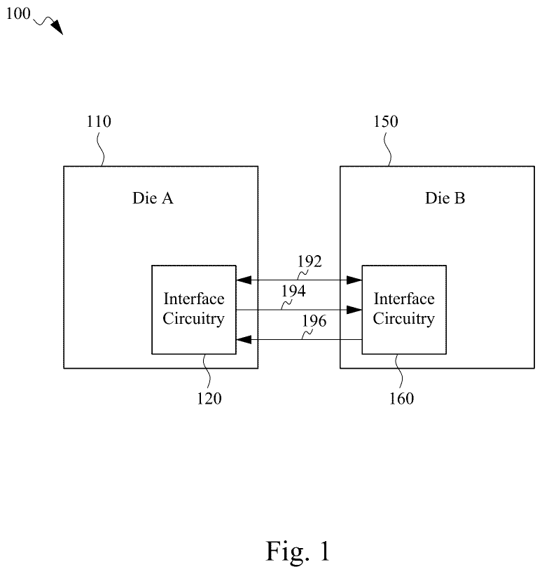

FIG. 1 is a high-level block diagram of a communication system 100 that includes two semiconductor dies (labeled as “Die A” 110 and “Die B” 150), in accordance with some embodiments. In some embodiments, semiconductor dies 110 and 150 are incorporated within the same integrated circuit (IC) package based on a 2.5-dimensional (2.5D) packaging technology or a three-dimensional (3D) packaging technology. In some other embodiments, semiconductor dies 110 and 150 are not within the same IC package.

In FIG. 1, semiconductor die 110 includes an interface circuitry 120, and semiconductor die 150 includes an interface circuitry 160. In FIG. 1, communication system 100 further includes a bi-directional data lane 192 and two clock lanes 194 and 196 communicatively coupling interface circuitry 120 and interface circuitry 160. In this example, only one data lane 192 is in FIG. 1. In some embodiments, communication system 100 includes one or more other data lanes between and communicatively coupling interface circuitry 120 and interface circuitry 160. In some embodiments, each one of data lane 192 and clock lanes 194 and 196 is based on a conductive structure, such as a single conductive line for carrying a single-ended signal or a pair of conductive lines for carrying a pair of differential signals.

Various examples in this disclosure correspond to the implementations based on single-ended signals. In some other embodiments, the examples in this disclosure are also applicable to the implementations based on differential signals.

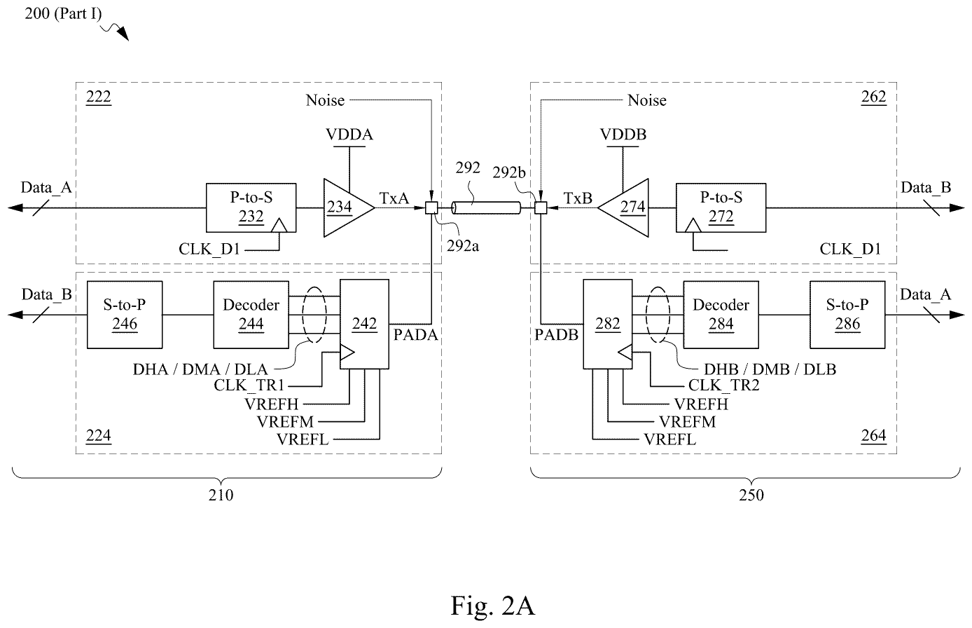

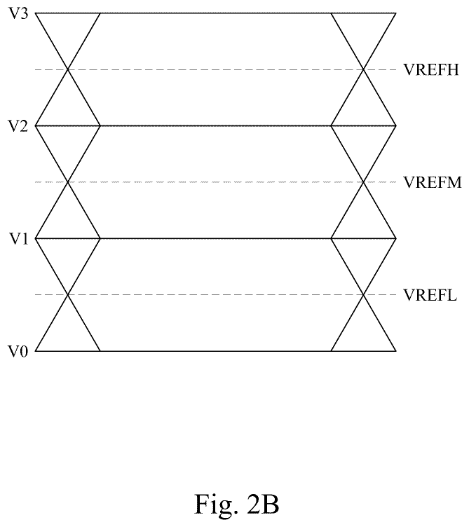

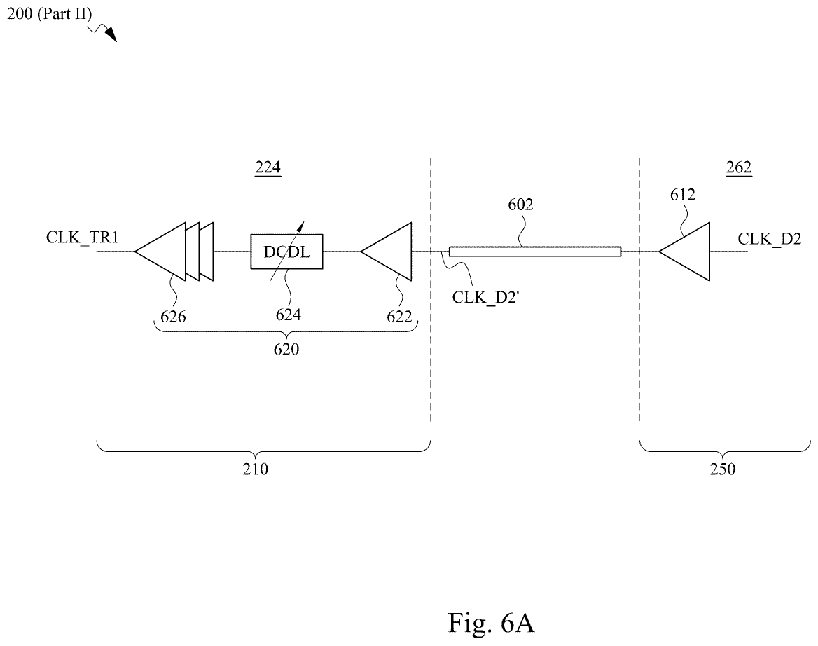

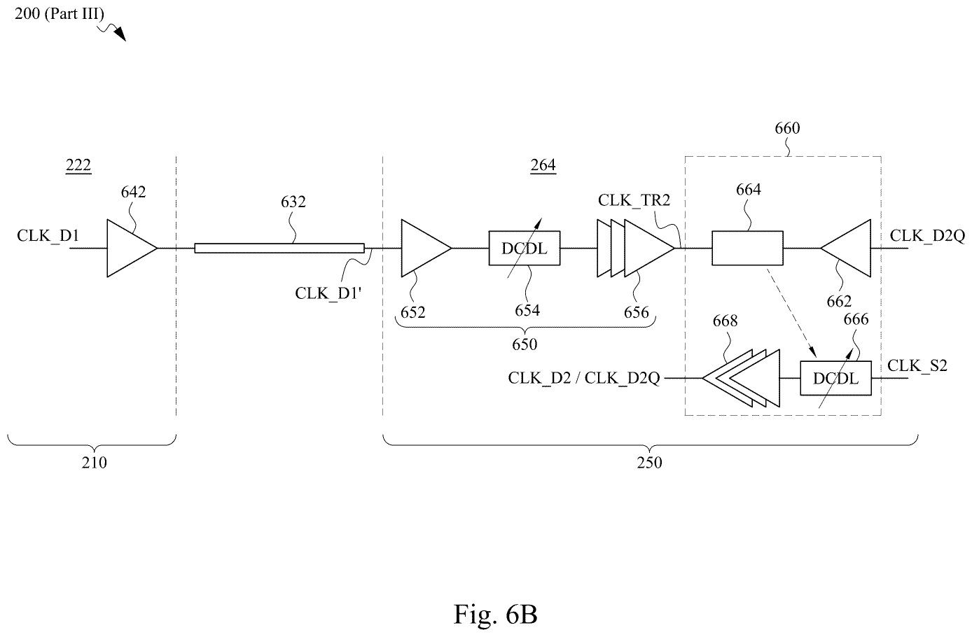

FIG. 2A is a functional block diagram of a first portion of a communication system (labeled as 200 (Part I)), in accordance with some embodiments. In some embodiments, communication system 200 corresponds to communication system 100 in FIG. 1. In FIG. 2A, communication system 200 includes a side A die 210 and a side B die 250 corresponding to semiconductor dies 110 and 150 in FIG. 1. In FIG. 2A, communication system 200 further includes a bi-directional data lane 292 that is based on a conductive structure. In this example, data lane 292 includes a first terminal 292a electrically coupled to side A die 210 and a second terminal 292b electrically coupled to side B die 250. In some embodiments, data lane 292 corresponds to data lane 192 in FIG. 1. In addition, other portions of communication system 200 are further described in connection with FIGS. 6A and 6B.

In FIG. 2A, side A die 210 includes a first interface circuitry that includes a first transmission circuitry 222 and a first receiving circuitry 224. In some embodiments, first transmission circuitry 222 is configured to output a first component signal TxA based on first data Data_A to first terminal 292a of data lane 292. First transmission circuitry 222 includes a first parallel-to-serial converter (labeled “P-to-S” in FIG. 2A and also referred to as a first serializer) 232 operated based on a first data clock signal CLK_D1. In some embodiments, first parallel-to-serial converter 232 is configured to receive first data Data_A in a parallel format from another portion of side A die 210 and convert first data Data_A into a serial format. First transmission circuitry 222 further includes a first output driver 234 that is energized by a first supply voltage having a first supply voltage level VDDA. In some embodiments, first output driver 234 is configured to match an impedance of data lane 292 and output first component signal TxA based on first data Data_A in the serial format from first parallel-to-serial converter 232.

In FIG. 2A, first receiving circuitry 224 is configured to receive a first combined signal PADA at first terminal 292a of data lane 292. In some embodiments, first combined signal PADA is based on first component signal TxA from first transmission circuitry 222 and a second component signal TxB from side B die 250 through data lane 292 (with a delay caused by data lane 292). In some embodiments, first combined signal PADA further includes the noise from neighboring data lanes and/or other electrical components of side A die 210, and/or the noise from side B die 250 through data lane 292. In some embodiments, second component signal TxB is based on second data Data_B of side B die 250 and from a second output driver 274 that is energized by a second supply voltage having a second supply voltage level VDDB. In some embodiments, first supply voltage level VDDA of the first supply voltage and second supply voltage level V DDB of the second supply voltage are based on second supply voltage level V DDB being n times first supply voltage level VDDA or first supply voltage level VDDA being n times second supply voltage level VDDB. In some embodiments, n is a real number greater than 1.0. In some embodiments, n is equal to or greater than 1.5. In some embodiments, n ranges from 1.8 to 2.4. In FIG. 2A as a non-limiting example, second supply voltage level VDDB is n times first supply voltage level VDDA (n ranging, e.g., from 1.8 to 2.4). Of course, in some embodiments, first supply voltage level VDDA is set to be n times second supply voltage level VDDB, based on a fixed configuration or being configurable or programmable.

In some embodiments, first receiving circuitry 224 is configured to extract second data Data_B from the first combined signal PADA. In this example, first receiving circuitry 224 includes a first data extraction circuitry 242 operated based on a first triggering clock signal CLK_TR1, a first decoder 244, and a first serial-to-parallel converter (also referred to as a first de-serializer) 246. In some embodiments, first receiving circuitry 224 is configured to extract one or more of a reference data DHA based on comparing first combined signal PADA against a high reference voltage level VREFH, a reference data DM A based on comparing first combined signal PADA against an intermediate reference voltage level VREFM, and/or a reference data DLA based on comparing first combined signal PADA against a low reference voltage level VREFL. In some embodiments, first decoder 244 is configured to decode second data Data_B in a serial format based on a logic combination of reference data DHA, DMA, and/or DLA. In a non-limiting example as second supply voltage level VDDB is n times first supply voltage level VDDA, first decoder 244 obtains second data Data_B in a serial format based on reference data DMA, which is extracted based on comparing first combined signal PADA against intermediate reference voltage level VREFM. In some embodiments, first serial-to-parallel converter 246 is configured to receive second data Data_B in the serial format from first decoder 244, convert second data Data_B into a parallel format, and output second data Data_B in the parallel format to another portion of side A die 210.

Also, in FIG. 2A, side B die 250 includes a second interface circuitry that includes a second transmission circuitry 262 and a second receiving circuitry 264. In some embodiments, second transmission circuitry 262 is configured to output second component signal TxB based on second data Data_B to second terminal 292b of data lane 292. Second transmission circuitry 262 includes a second parallel-to-serial converter (labeled “P-to-S” in FIG. 2A and also referred to as a second serializer) 272 operated based on a second data clock signal CLK_D2. In some embodiments, second parallel-to-serial converter 272 is configured to receive second data Data_B in a parallel format from another portion of side B die 260 and convert second data Data_B into a serial format. Second transmission circuitry 262 further includes a second output driver 274 that is energized by the second supply voltage having second supply voltage level VDDB. In some embodiments, second output driver 274 is configured to match an impedance of data lane 292 and output second component signal TxB based on second data Data_B in the serial format from second parallel-to-serial converter 272.

In FIG. 2A, second receiving circuitry 264 is configured to receive a second combined signal PADB at second terminal 292b of data lane 292. In some embodiments, second combined signal PADB is based on second component signal TxB from second transmission circuitry 262 and first component signal TxA from side A die 210 through data lane 292 (with a delay caused by data lane 292). In some embodiments, second combined signal PA DB further includes the noise from neighboring data lanes and/or other electrical components of side B die 250, and/or the noise from side A die 210 through data lane 292.

In some embodiments, second receiving circuitry 264 is configured to extract first data Data_A from the second combined signal PADB. In this example, second receiving circuitry 264 includes a second data extraction circuitry 282 operated based on a second triggering clock signal CLK_TR2, a second decoder 284, and a second serial-to-parallel converter (also referred to as a second de-serializer) 286. In some embodiments, second receiving circuitry 264 is configured to extract one or more of a reference data DHB based on comparing second combined signal PA DB against high reference voltage level VREFH, a reference data DM B based on comparing second combined signal PADB against intermediate reference voltage level VREFM, and/or a reference data DLB based on comparing second combined signal PADB against low reference voltage level VREFL. In some embodiments, second decoder 284 is configured to decode first data Data_A in a serial format based on a logic combination of reference data DHB, DM B, and/or DLB. In a non-limiting example as second supply voltage level VDDB is n times first supply voltage level VDDA, serial decoder 284 obtains first data Data_A in a serial format based on a logic combination of reference data DHB, DMB, and DLB. In some embodiments, second serial-to-parallel converter 286 is configured to receive first data Data_A in the serial format from second decoder 284, convert first data Data_A into a parallel format, and output first data Data_A in the parallel format to another portion of side B die 250.

In some embodiments, first component signal TxA is based on first data Data_A in the serial format, which is further based on first data clock signal CLK_D1. In some embodiments, second component signal TxB is based on second data Data_B in the serial format, which is further based on second data clock signal CLK_D2. In some embodiments, compared to the output signal of first parallel-to-serial converter 232, first component signal TxA is delayed by a delay Td_a1 of first output driver 234. In some embodiments, compared to the output signal of second parallel-to-serial converter 272, second component signal TxB is delayed by a delay Td_b1 of second output driver 234. In some embodiments, first combined signal PADA includes at least the first component signal TxA and second component signal TxB with a delay Td_d of data lane 292. In some embodiments, second combined signal PA DB includes at least the second component signal TxB and first component signal TxA with the delay Td_d of data lane 292.

In some embodiments, the first receiving circuitry 224 is further configured to receive a first reference clock signal (CLK_D2′, not shown in FIG. 2A) from side B die 250 through a first clock lane (not shown in FIG. 2A). In some embodiments, first reference clock signal CLK_D2′ corresponds to the second data clock signal CLK_D2 with a delay (e.g., a delay Td_b2 of a third output driver and delay Td_c1 of the first clock lane as further described in FIG. 6A). In some embodiments, first receiving circuitry 224 is configured to extract second data Data_B from first combined signal PADA based on first triggering clock signal CLK_TR1 that is derived based on first reference clock signal CLK_D2′. In some embodiments, first triggering clock signal CLK_TR1 is derived based on delaying first reference clock signal CLK_D2′ by a quarter-phase.

Similarly, at side B die 250, the second receiving circuitry 264 is further configured to receive a second reference clock signal (CLK_D1′, not shown in FIG. 2A) from side A die 210 through a second clock lane (not shown in FIG. 2A). In some embodiments, second reference clock signal CLK_D1′ corresponds to the first data clock signal CLK_D1 with a delay (e.g., a delay Td_a2 of a fourth output driver and delay Td_c2 corresponding to the second clock lane as further described in FIG. 6B). In some embodiments, delay Td_c1, delay Td_c2, and delay Td_d are deemed the same (or the difference therebetween is nominal) for the purposes of deriving the corresponding clock signals. In some embodiments, delay Td_a1 and delay Td_a2 are deemed the same (or the difference therebetween is ignorable), and delay Td_b1 and delay Td_b2 are deemed the same (or the difference therebetween is ignorable). In some embodiments, second receiving circuitry 264 is configured to extract first data Data_A from second combined signal PA DB based on second triggering clock signal CLK_TR2 that is derived based on second reference clock signal CLK_D1′. In some embodiments, second triggering clock signal CLK_TR2 is derived based on delaying second reference clock signal CLK_D1′ by a quarter-phase (i.e., lagging by 90 degrees in phase).

In some embodiments as described above, second supply voltage level VDDB is n times first supply voltage level VDDA, or first supply voltage level VDDA is n times second supply voltage level VDDB. In some embodiments, the factor ‘n’ is determinable based on the sensitivity of the corresponding data extraction circuitry (e.g., first data extraction circuitry 242 and/or second data extraction circuitry 282) in view of first supply voltage level VDDA and/or second supply voltage level VDDB. In one example, based on first supply voltage level VDDA being 0.4 V and second supply voltage level VDDB being n times first supply voltage level VDDA, n is greater than 1.8. In another example, based on first supply voltage level VDDA being 1.0 V and second supply voltage level VDDB being n times first supply voltage level VDDA, n is 1.5. In some embodiments, n is greater than 3 or 4 to ease the sensitivity requirement for the corresponding data extraction circuitry, and at the cost of the increased circuit complexity to obtain the suitable reference voltage levels (e.g., high reference voltage level VREFH, intermediate reference voltage level VREFM, and/or low reference voltage level VREFL).

FIG. 2B is a signal diagram of voltage levels of various signal components in communication system 200 in FIG. 2A, in accordance with some embodiments. In this non-limiting example, data lane 292 in FIG. 2A is configured to carry single-ended signals, and first output driver 234 and second output driver 274 are configured to match the impedance of data lane 292. Also, in this non-limiting example, second supply voltage level VDDB is n times first supply voltage level VDDA (e.g., n being equal to or greater than 1.5 and/or ranging from 1.8 to 2.4).

In FIG. 2B as a non-limiting example, based on first output driver 234 pulling first component signal TxA to a logic low level at side A die 210 and second output driver 274 pulling second component signal TxB to a logic low level at side B die 250, the combined signal on data lane 292 is at a voltage level V0, which corresponds to a ground reference voltage level (or 0 volt (V)). Based on first output driver 234 pulling first component signal TxA to a logic high level at side A die 210 and second output driver 274 pulling second component signal TxB to a logic low level at side B die 250, the combined signal on data lane 292 is at a voltage level V1, which corresponds to VDDA/2. Based on first output driver 234 pulling first component signal TxA to a logic low level at side A die 210 and second output driver 274 pulling second component signal TxB to a logic high level at side B die 250, the combined signal on data lane 292 is at a voltage level V2, which corresponds to VDDB/2. Moreover, based on first output driver 234 pulling first component signal TxA to a logic high level at side A die 210 and second output driver 274 pulling second component signal TxB to a logic high level at side B die 250, the combined signal on data lane 292 is at a voltage level V3, which corresponds to (VDDA/2+VDDB/2).

In FIG. 2B as a non-limiting example, high reference voltage level VREFH is used to determine if a voltage level of the combined signal corresponds to voltage level V3 or one of voltage levels V2, V1, and V0; intermediate reference voltage level VREFM is used to determine if the voltage level of the combined signal corresponds to one of voltage levels V3 and V2 or one of voltage levels V1 and V0; and low reference voltage level VREFL is used to determine if the voltage level of the combined signal corresponds to one of voltage levels V3, V2, and V1 or voltage level V0. In some embodiments, high reference voltage level VREFH is determined based on (VDDA/4+VDDB/2) or VDDA*(2n+1)/4. In some embodiments, intermediate reference voltage level VREFM is determined based on (VDDA/4+VDDB/4) or VDDA*(n+1)/4. In some embodiments, low reference voltage level VREFL is determined based on VDDA/4.

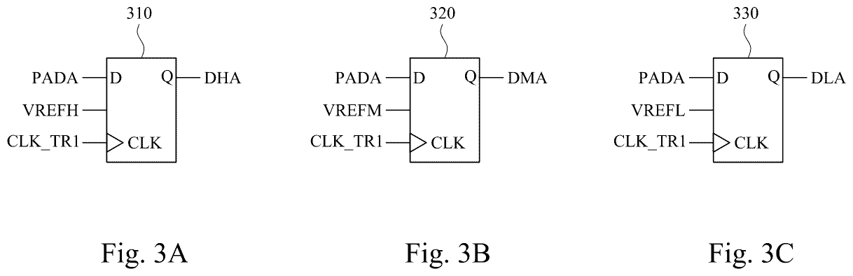

In some embodiments, first data extraction circuitry 242 of side A die 210 in FIG. 2A includes one or more flip-flop circuits, as further described based on the examples in FIGS. 3A-3C.

FIG. 3A is a circuit diagram of a flip-flop circuit 310 in a data extraction circuitry (e.g., first data extraction circuitry 242) of side A die 210 in FIG. 2A for extracting reference data DHA based on comparing first combined signal PADA against high reference voltage level VREFH, in accordance with some embodiments. Signals that are the same as those in FIG. 2A are given the same reference labels, and the description thereof is simplified or omitted. In FIG. 3A, a data input terminal (D) of flip-flop circuit 310 is configured to receive first combined signal PADA, a data output terminal (Q) of flip-flop circuit 310 is configured to output reference data DHA, and a clock terminal (CLK) of flip-flop circuit 310 is configured to receive first triggering clock CLK_TR1. Moreover, in this non-limiting example, whether first combined signal PADA corresponds to a logic high or a logic low is determined by flip-flop circuit 310 based on comparing first combined signal PADA against high reference voltage level VREFH.

FIG. 3B is a circuit diagram of a flip-flop circuit 320 in a data extraction circuitry (e.g., first data extraction circuitry 242) of side A die 210 in FIG. 2A for extracting reference data DM A based on comparing first combined signal PADA against intermediate reference voltage level VREFM, in accordance with some embodiments. Signals that are the same as those in FIG. 2A are given the same reference labels, and the description thereof is simplified or omitted. In FIG. 3B, a data input terminal (D) of flip-flop circuit 320 is configured to receive first combined signal PADA, a data output terminal (Q) of flip-flop circuit 320 is configured to output reference data DMA, and a clock terminal (CLK) of flip-flop circuit 320 is configured to receive first triggering clock CLK_TR1. Moreover, in this non-limiting example, whether first combined signal PADA corresponds to a logic high or a logic low is determined by flip-flop circuit 320 based on comparing first combined signal PADA against intermediate reference voltage level VREFM.

FIG. 3C is a circuit diagram of a flip-flop circuit 330 in a data extraction circuitry (e.g., first data extraction circuitry 242) of side A die 210 in FIG. 2A for extracting reference data DLA based on comparing first combined signal PADA against low reference voltage level VREFL, in accordance with some embodiments. Signals that are the same as those in FIG. 2A are given the same reference labels, and the description thereof is simplified or omitted. In FIG. 3C, a data input terminal (D) of flip-flop circuit 330 is configured to receive first combined signal PADA, a data output terminal (Q) of flip-flop circuit 330 is configured to output reference data DLA, and a clock terminal (CLK) of flip-flop circuit 330 is configured to receive first triggering clock CLK_TR1. Moreover, in this non-limiting example, whether first combined signal PADA corresponds to a logic high or a logic low is determined by flip-flop circuit 330 based on comparing first combined signal PADA against low reference voltage level VREFL.

In some embodiments, based on second supply voltage level VDDB is n times first supply voltage level VDDA (e.g., n being equal to or greater than 1.5 and/or ranging from 1.8 to 2.4), only reference data DMA is needed to decode second data Data_B. Therefore, in some embodiments, flip-flop circuit 310 and flip-flop circuit 330 are omitted or disabled in first data extraction circuitry 242.

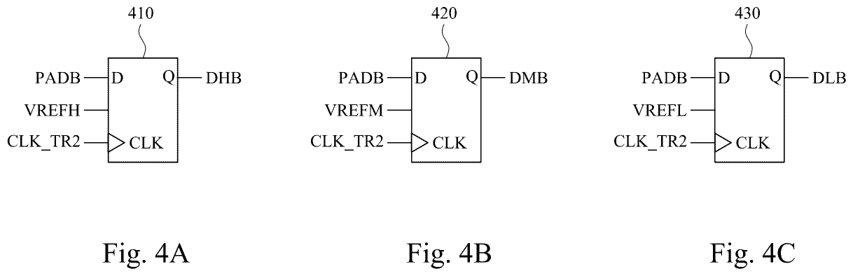

In addition, in some embodiments, second data extraction circuitry 282 of side B die 250 in FIG. 2A includes one or more flip-flop circuits, as further described based on the examples in FIGS. 4A-4C.

FIG. 4A is a circuit diagram of a flip-flop circuit 410 in a data extraction circuitry (e.g., second data extraction circuitry 282) of side B die 250 in FIG. 2A for extracting reference data DHB based on comparing second combined signal PADB against high reference voltage level VREFH, in accordance with some embodiments. Signals in FIG. 4A that are the same as those in FIG. 2A are given the same reference labels, and the description thereof is simplified or omitted. In FIG. 4A, a data input terminal (D) of flip-flop circuit 410 is configured to receive second combined signal PADB, a data output terminal (Q) of flip-flop circuit 410 is configured to output reference data DHB, and a clock terminal (CLK) of flip-flop circuit 410 is configured to receive second triggering clock CLK_TR2. Moreover, in this non-limiting example, whether second combined signal PA DB corresponds to a logic high or a logic low is determined by flip-flop circuit 410 based on comparing second combined signal PADB against high reference voltage level VREFH.

FIG. 4B is a circuit diagram of a flip-flop circuit 420 in a data extraction circuitry (e.g., second data extraction circuitry 282) of side B die 250 in FIG. 2A for extracting reference data DM B based on comparing second combined signal PADB against intermediate reference voltage level VREFM, in accordance with some embodiments. Signals in FIG. 4B that are the same as those in FIG. 2A are given the same reference labels, and the description thereof is simplified or omitted. In FIG. 4B, a data input terminal (D) of flip-flop circuit 420 is configured to receive second combined signal PA DB, a data output terminal (Q) of flip-flop circuit 420 is configured to output reference data DM B, and a clock terminal (CLK) of flip-flop circuit 420 is configured to receive second triggering clock CLK_TR2. Moreover, in this non-limiting example, whether second combined signal PADB corresponds to a logic high or a logic low is determined by flip-flop circuit 420 based on comparing second combined signal PA DB against intermediate reference voltage level VREFM.

FIG. 4C is a circuit diagram of a flip-flop circuit 430 in a data extraction circuitry (e.g., second data extraction circuitry 282) of side B die 250 in FIG. 2A for extracting reference data DLB based on comparing second combined signal PADB against low reference voltage level VREFL, in accordance with some embodiments. Signals in FIG. 4C that are the same as those in FIG. 2A are given the same reference labels, and the description thereof is simplified or omitted. In FIG. 4C, a data input terminal (D) of flip-flop circuit 430 is configured to receive second combined signal PADB, a data output terminal (Q) of flip-flop circuit 430 is configured to output reference data DLB, and a clock terminal (CLK) of flip-flop circuit 430 is configured to receive second triggering clock CLK_TR2. Moreover, in this non-limiting example, whether second combined signal PA DB corresponds to a logic high or a logic low is determined by flip-flop circuit 430 based on comparing second combined signal PADB against low reference voltage level VREFL.

In some embodiments, based on second supply voltage level VDDB is n times first supply voltage level VDDA (e.g., n being equal to or greater than 1.5 and/or ranging from 1.8 to 2.4), reference data DHB, DMB, and DLB are used to decode first data Data_A. Therefore, in some embodiments, flip-flop circuits 410, 420, and 430 are all included in second data extraction circuitry 282.

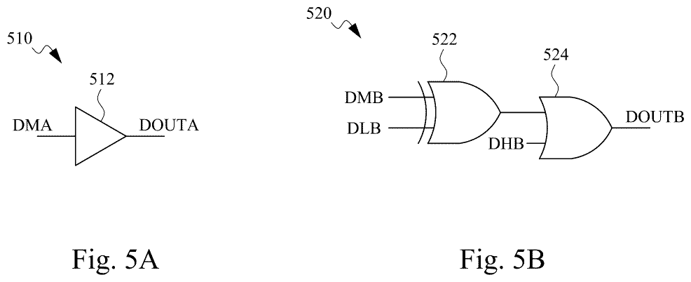

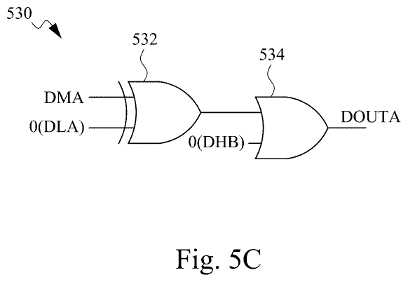

FIG. 5A is a circuit diagram of a decoding circuit 510 in a receiving circuitry (e.g., first receiving circuitry 224) of side A die 210 in FIG. 2A, in accordance with some embodiments. Signals in FIG. 5A that are the same as those in FIG. 2A are given the same reference labels, and the description thereof is simplified or omitted. In some embodiments, based on second supply voltage level VDDB is n times first supply voltage level VDDA (e.g., n being equal to or greater than 1.5 and/or ranging from 1.8 to 2.4), reference data DM A is usable as the decoded second data Data_B. In this example, decoding circuit 510 includes a buffer 512 that includes an input terminal configured to receive reference data DM A and an output terminal configured to output second data Data_B in the serial format.

FIG. 5B is a circuit diagram of a decoding circuit 520 in a receiving circuitry (e.g., second receiving circuitry 264) of side B die 250 in FIG. 2A, in accordance with some embodiments. Signals in FIG. 5B that are the same as those in FIG. 2A are given the same reference labels, and the description thereof is simplified or omitted. In some embodiments, based on second supply voltage level VDDB is n times first supply voltage level VDDA (e.g., n being equal to or greater than 1.5 and/or ranging from 1.8 to 2.4), first data Data_A is decoded based on a logic combination of the reference data DHB, reference data DM B, and reference data DLB.

In FIG. 5B as a non-limiting example, decoding circuit 520 includes an exclusive or (XOR) gate 522 and an OR gate 524. The input terminals of XOR gate 522 are configured to receive reference data DM B and reference data DM L and output an XOR output to OR gate 524. OR gate 524 includes one input terminal configured to receive the XOR output from XOR gate 522, another input terminal configured to receive reference data DHB, and output a decoded data DOUTB as the decoded first data Data_A.

Therefore, provided DOUT represents a decoded binary value of the decoded data at a given time, and DH (e.g., DHB), DM (e.g., DMB), and DL (e.g., DLB) represent corresponding binary values of the reference databased on various reference levels VREFH, VREFM, and VREFL at the given time, the decoded data is based on the logic combination of DOUT=DH OR (DM XOR DL).

FIG. 5C is a circuit diagram of a decoding circuit 530 in a receiving circuitry (e.g., first receiving circuitry 224) of side A die 210 in FIG. 2A, in accordance with some embodiments. Signals in FIG. 5C that are the same as those in FIG. 2A are given the same reference labels, and the description thereof is simplified or omitted. In FIG. 5C as a non-limiting example and as an alternative to decoding circuit 510 in FIG. 5A, decoding circuit 530 of first receiving circuitry 2 includes an XOR gate 532 and an OR gate 534 configured in a manner similar to decoding circuit 520. In some embodiments, this is because the circuit macro for the decoding circuit is reused for all the dies communicating with one another based on the examples in this disclosure, but subsequently controlled or configured to function at a lower supply-voltage side or a higher-supply voltage side. In this regard, as a nonlimiting example, decoding circuit 530 as used at side A die 210 (i.e., a lower supply-voltage side), one input terminal of X OR gate 532 is configured to receive reference data DMA, and another input terminal of XOR gate 532 is configured to receive reference data DLA that is set to logic 0 (or simply receiving logic 0). Also, one input terminal of OR gate 534 is configured to receive the output from XOR gate 532, and another input terminal of OR gate 534 is configured to receive reference data DHA that is set to logic 0 (or simply receiving logic 0). In this example, OR gate 534 is configured to output a decoded data DOUTA as the decoded second data Data_B.

FIG. 6A is a circuit diagram of a second portion of communication system (labeled as 200 (Part II)) in FIG. 2A regarding transmitting second data clock signal CLK_D2 to side A die 210 and generating first triggering clock CLK_TR1 at side A die 210, in accordance with some embodiments. Components and signals that are the same as those in FIG. 2A are given the same reference numbers and reference labels, and the description thereof is simplified or omitted.

In FIG. 6A, communication system 200 includes the first clock lane 602 that is based on a conductive structure between and communicatively coupling side A die 210 and side B die 250. In this example, second transmission circuitry 262 of side B die 250 further includes a third output driver 612 that is configured to receive second data clock signal CLK_D2 and output second data clock signal CLK_D2 to side A die 210 through first clock lane 602. In some embodiments, first reference clock signal CLK_D2′ corresponds to second data clock signal CLK_D2 with a delay based on delay Td_b2 of third output driver 612 and delay Td_c1 of first clock lane 602.

In FIG. 6A, first receiving circuitry 224 of side A die 210 further includes a delay circuitry 620 that is configured to receive first reference clock signal CLK_D2′ and derive first triggering clock signal CLK_TR1 based on delaying first reference clock signal CLK_D2′ by a quarter phase. In some embodiments, delay circuitry 620 includes an input buffer 622, a digital control delay line (with a label “DCDL”) 624, and one or more driving buffers 626. In some embodiments, the quarter-phase delay is based on the delays of input buffer 622, digital control delay line 624, and one or more driving buffers 626.

FIG. 6B is a circuit diagram of a third portion of communication system (labeled as 200 (Part III)) in FIG. 2A regarding transmitting first data clock signal CLK_D1 to side B die 250 and generating second triggering clock CLK_TR2 and second data clock signal CLK_D2 at side B die 250, in accordance with some embodiments. Components and signals that are the same as those in FIG. 2A are given the same reference numbers and reference labels, and the description thereof is simplified or omitted.

In FIG. 6B, communication system 200 includes the second clock lane 632 that is based on a conductive structure between and communicatively coupling side A die 210 and side B die 250. In this example, first transmission circuitry 222 of side A die 210 further includes a fourth output driver 642 that is configured to receive first data clock signal CLK_D1 and output first data clock signal CLK_D1 to side B die 250 through second clock lane 632. In some embodiments, second reference clock signal CLK_D1′ corresponds to first data clock signal CLK_D1 with a delay based on delay Td_a2 of fourth output driver 642 and delay Td_c2 of second clock lane 632.

In FIG. 6B, second receiving circuitry 264 of side B die 250 further includes a delay circuitry 650 that is configured to receive second reference clock signal CLK_D1′ and derive second triggering clock signal CLK_TR2 based on delaying second reference clock signal CLK_D1′ by a quarter phase. In some embodiments, delay circuitry 650 includes an input buffer 652, a digital control delay line (with a label “DCDL”) 654, and one or more driving buffers 656. In some embodiments, the quarter-phase delay is based on the delays of input buffer 652, digital control delay line 654, and one or more driving buffers 656.

Moreover, in FIG. 6B, second receiving circuitry 264 of side B die 250 further includes a phase-adjustment circuitry 660 that is configured to, based on the second supply voltage level VDDB is n times the first supply voltage level VDDA, generate second data clock signal CLK_D2 based on a phase of the second reference clock signal CLK_D1′. In this example, second triggering clock signal CLK_TR2 incorporates the phase information regarding the phase of second reference clock signal CLK_D1′ with a quarter-phase delay. In this example, phase-adjustment circuitry 660 is configured to derive second data clock signal CLK_D2 (or a shifted second data clock signal CLK_D2Q corresponding to second data clock signal CLK_D2 with a quarter-phase delay) based on comparing the phases of second triggering clock signal CLK_TR2 and shifted second data clock signal CLK_D2Q.

In FIG. 6B, phase-adjustment circuitry 660 includes an input buffer 662, a phase comparator 664, a digital control delay line (with a label “DCDL”) 666, and one or more driving buffers 668. In some embodiments, phase comparator 664 compares the phase of second triggering clock signal CLK_TR2 from delay circuitry 650 and the phase of shifted second data clock signal CLK_D2Q from input buffer 662 and provides a control signal to control the operation of digital control delay line 666. In some embodiments, digital control delay line 666 is configured to receive and delay a system clock signal CLK_S2 of side B die 250, and output through one or more driving buffers 668 second data clock signal CLK_D2 or shifted second data clock signal CLK_D2, which is in turn usable by other components second data clock signal CLK_D2.

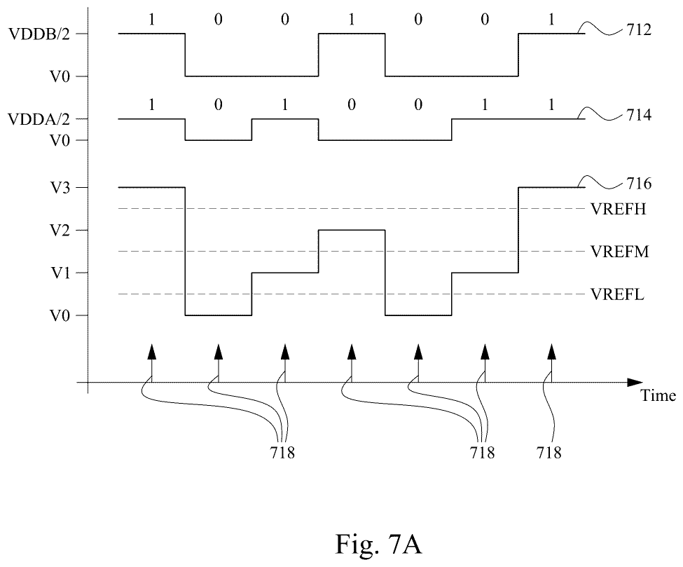

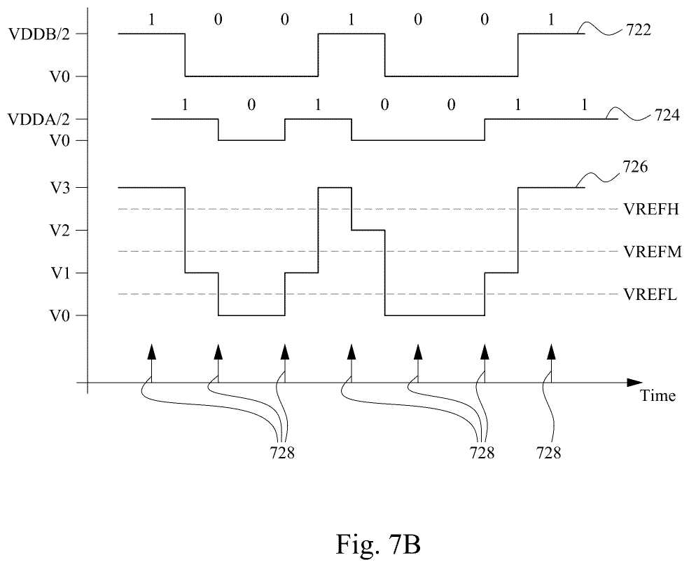

FIGS. 7A-7B are signal timing diagrams of various signals at the interface circuitry at side A die 210 in the communication system in FIGS. 2A, 2B, 6A, and 6B, in accordance with some embodiments. In FIGS. 7A-7B, vertical axis represents voltage levels of various signals, and horizontal axis represents time. In this non-limiting example, second supply voltage level V DDB that energizes an output driver of side B die 250 is n times first supply voltage level VDDA that energizes an output driver of side A die 210, n ranging, e.g., from 1.8 to 2.4. Signals that are the same as those in FIGS. 2A, 2B, 6A, and 6B are given the same reference labels, and the description thereof is simplified or omitted.

FIG. 7A includes a signal plot 712 representing a delayed second component signal TxB at first terminal 292a of data lane 292 in FIG. 2A; a signal plot 714 representing first component signal TxA at first terminal 292a of data lane 292; and a signal plot 716 representing first combined signal PADA observable at first terminal 292a of data lane 292. In this example, delayed second component signal TxB switches between VDDB/2 and the ground reference voltage level V0 and carries digital data of {1001001}; and first component signal TxA switches between VDDA/2 and the ground reference voltage level V0 and carries digital data of {1010011}. In this example, the phase of delayed second component signal TxB (signal plot 712) and phase of first component signal TxA (signal plot 714) are aligned.

In FIG. 7A, the arrows 718 represent the triggering edges of first triggering clock signal CLK_TR1, which correspond to signal CLK_D2′ delayed by a quarter-phase as illustrated in FIG. 6A. In this example, based on the high reference voltage level VREFH, the extracted reference data DHA correspond to {1000001}; based on the intermediate reference voltage level VREFM, the extracted reference data DM A correspond to {1001001}; and based on the low reference voltage level VREFL, the extracted reference data DLA correspond to {1011011}. Here, the extracted reference data DM A is usable as the decoded digital data carried by second component signal TxB.

For example, assuming VDDA=0.4 V and VDDB=0.8V, at a given moment, the voltage levels of first combined signal PADA, the digital value of first component signal TxA (DA), the digital value of the delayed second component signal TxB (DB), and the digital values of reference data DHA, DMA, and DLA have a relationship as presented in the table below. As shown in the table, the extracted reference data DMA is the same as the digital value of delayed second component signal TxB (DB).

| | | | DHA | DMA | DLA |
|---|---|---|---|---|---|
| | | PADA | (VREFH = | (VREFH = | (VREFH = |
| DA | DB | (V) | 0.5 V) | 0.3 V) | 0.1 V) |
| 0 | 0 | 0 | 0 | 0 | 0 |
| 1 | 0 | 0.2 | 0 | 0 | 1 |
| 0 | 1 | 0.4 | 0 | 1 | 1 |
| 1 | 1 | 0.6 | 1 | 1 | 1 |

FIG. 7B includes a signal plot 722 representing a delayed second component signal TxB at first terminal 292a of data lane 292 in FIG. 2A; a signal plot 724 representing first component signal TxA at first terminal 292a of data lane 292; and a signal plot 726 representing first combined signal PADA observable at first terminal 292a of data lane 292. Similar to the example in FIG. 7A, delayed second component signal TxB switches between VDDB/2 and the ground reference voltage level V0 and carries digital data of {1001001}; and first component signal TxA switches between VDDA/2 and the ground reference voltage level V0 and carries digital data of {1010011}. Compared to the example in FIG. 7A, the phase of delayed second component signal TxB (signal plot 722) and phase of first component signal TxA (signal plot 724) are misaligned (e.g., by a quarter-phase).

In FIG. 7B, the arrows 728 represent the triggering edges of first triggering clock signal CLK_TR1, which correspond to signal CLK_D2′ delayed by a quarter-phase as illustrated in FIG. 6A. In this example, based on the high reference voltage level VREFH, the extracted reference data DHA correspond to {100?001}; based on the intermediate reference voltage level VREFM, the extracted reference data DM A correspond to {1001001}; and based on the low reference voltage level VREFL, the extracted reference data DLA correspond to {1?110?1}. The “?” here represents the uncertainty of the decoded digital value, which depends on the misalignment of the phases between delayed second component signal TxB and first component signal TxA. However, regardless of the phase misalignment, the extracted reference data DMA based on intermediate reference voltage level VREFM is still usable as the decoded digital data carried by second component signal TxB. In some embodiments, based on the intermediate reference voltage level VREFM, first component signal TxA is considered as noise in first combined signal PADA for decoding the data carried by second component signal TxB.

Accordingly, in view of FIGS. 7A and 7B, for a lower-supply-voltage side receiving and decoding data from a higher-supply-voltage side, the intermediate reference voltage level VREFM and the corresponding extracted data are sufficient to decode the incoming data, and the alignment between the component signals observable at the receiving side is not required.

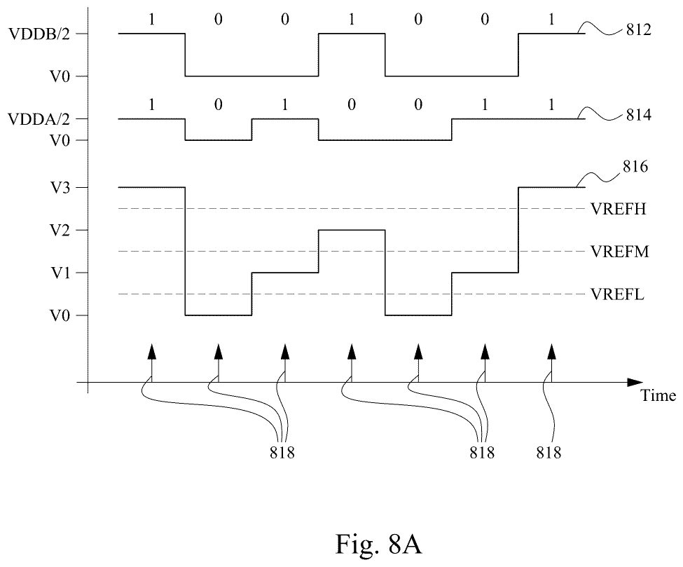

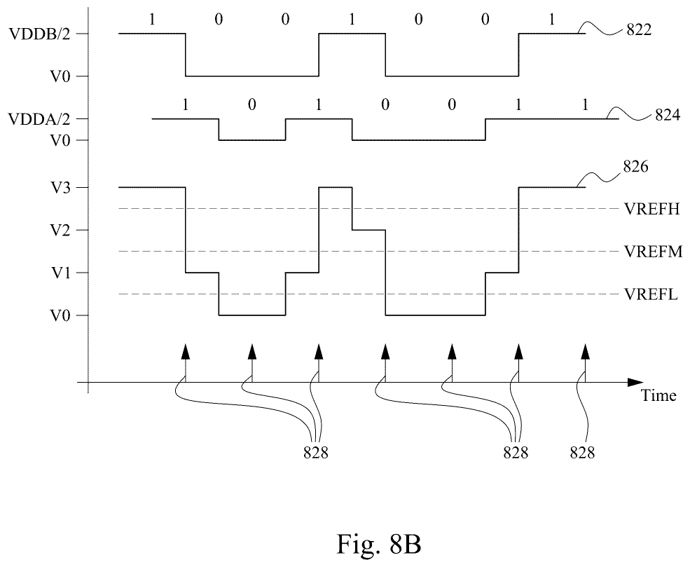

FIGS. 8A-8B are signal timing diagrams of various signals at the interface circuitry at side B die 250 in the communication system in FIGS. 2A, 2B, 6A, and 6B, in accordance with some embodiments. In FIGS. 8A-8B, vertical axis represents voltage levels of various signals, and horizontal axis represents time. In this non-limiting example, second supply voltage level V DDB that energizes an output driver of side B die 250 is n times first supply voltage level VDDA that energizes an output driver of side A die 210, n ranging, e.g., from 1.8 to 2.4. Signals that are the same as those in FIGS. 2A, 2B, 6A, and 6B are given the same reference labels, and the description thereof is simplified or omitted.

FIG. 8A includes a signal plot 812 representing second component signal TxB at second terminal 292b of data lane 292 in FIG. 2A; a signal plot 814 representing a delayed first component signal TxA at second terminal 292b of data lane 292; and a signal plot 816 representing second combined signal PADB observable at second terminal 292b of data lane 292. In this example, second component signal TxB switches between VDDB/2 and the ground reference voltage level V0 and carries digital data of {1001001}; and delayed first component signal TxA switches between VDDA/2 and the ground reference voltage level V0 and carries digital data of {1010011}. In this example, the phase of second component signal TxB (signal plot 812) and phase of the delayed first component signal TxA (signal plot 814) are aligned.

In FIG. 8A, the arrows 818 represent the triggering edges of second triggering clock signal CLK_TR2, which correspond to signal CLK_D1′ delayed by a quarter-phase as illustrated in FIG. 6B. In this example, based on the high reference voltage level VREFH, the extracted reference data DHB correspond to {1000001}; based on the intermediate reference voltage level VREFM, the extracted reference data DM B correspond to {1001001}; and based on the low reference voltage level VREFL, the extracted reference data DLB correspond to {1011011}. Here, the decoded data carried by first component signal TxA is decodable based on a logic combination of {DHB OR (DMB XOR DLB)} as similarly described in the example of FIG. 5B, which correspond to {1010011}.

For example, assuming VDDA=0.4 V and VDDB=0.8V, at a given moment, the voltage levels of second combined signal PADB, the digital value of the delayed first component signal TxA (DA), the digital value of second component signal TxB (DB), and the digital values of reference data DHB, DMB, and DLB have a relationship as presented in the table below. As shown in the table, the digital value of delayed first component signal TxA (DA) is decodable based on a logic combination of extracted reference data DHB, DMB, and DML.

| | | | DHA | DMA | DLA |
|---|---|---|---|---|---|
| | | PADB | (VREFH = | (VREFH = | (VREFH = |
| DA | DB | (V) | 0.5 V) | 0.3 V) | 0.1 V) |
| 0 | 0 | 0 | 0 | 0 | 0 |
| 0 | 1 | 0.2 | 0 | 1 | 1 |
| 1 | 0 | 0.4 | 0 | 0 | 1 |
| 1 | 1 | 0.6 | 1 | 1 | 1 |

FIG. 8B includes a signal plot 822 representing second component signal TxB at second terminal 292b of data lane 292 in FIG. 2A; a signal plot 824 representing a delayed first component signal TxA at second terminal 292b of data lane 292; and a signal plot 826 representing second combined signal PADB observable at second terminal 292b of data lane 292. Similar to the example in FIG. 8A, second component signal TxB switches between VDDB/2 and the ground reference voltage level V0 and carries digital data of {1001001}; and the delayed first component signal TxA switches between VDDA/2 and the ground reference voltage level V0 and carries digital data of {1010011}. Compared to the example in FIG. 8A, the phase of second component signal TxB (signal plot 822) and phase of the delayed first component signal TxA (signal plot 824) are misaligned (e.g., by a quarter-phase).

In FIG. 8B, the arrows 828 represent the triggering edges of second triggering clock signal CLK_TR2, which correspond to signal CLK_D1′ delayed by a quarter-phase as illustrated in FIG. 6B. In this example, based on the high reference voltage level VREFH, the extracted reference data DHB correspond to {?0?00?1}; based on the intermediate reference voltage level VREFM, the extracted reference data DM B correspond to {?0?? 0?1}; and based on the low reference voltage level VREFL, the extracted reference data DLB correspond to {101?011}. The “?” here represents the uncertainty of the decoded digital value, which depends on the misalignment of the phases between second component signal TxB and delayed first component signal TxA. In this example, reference data DHB, DM B, and DLA include too much uncertainty and thus render decoding of digital data carried by first component signal TxA based on reference data DHB, DMB, and DLA impossible or infeasible.

Accordingly, in view of FIGS. 8A and 8B, for a higher-supply-voltage side receiving and decoding data from a lower-supply-voltage side, the alignment between the component signals observable at the receiving side is preferred, which is achievable based on adjusting the phase of local data clock signal as in the example of FIG. 6B.

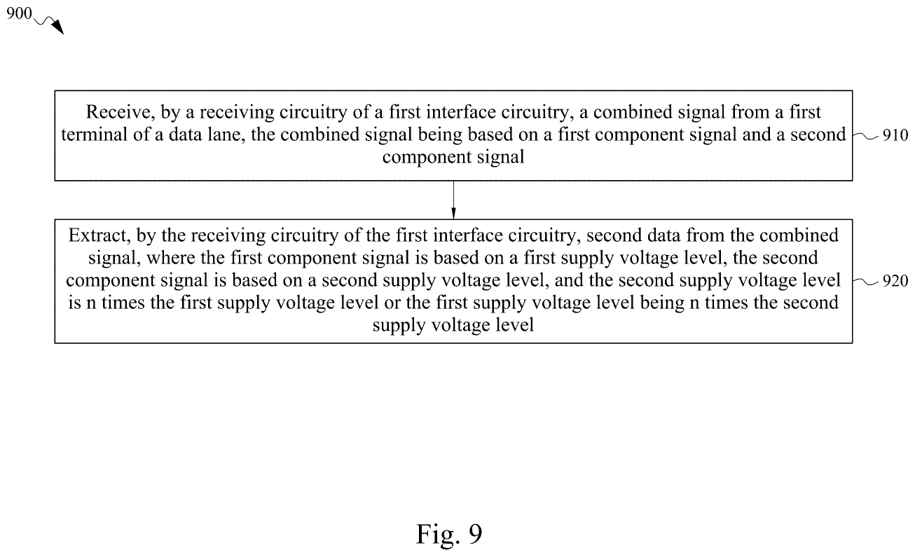

FIG. 9 is a flowchart of a communication method 900, in accordance with some embodiments. In some embodiments, communication method 900 corresponds to operations performed by one of side A die 210 or side B die 250 in FIG. 2A in conjunction with the other one of side A die 210 or side B die 250, in view of various examples in FIGS. 2B-8B. Method 900 includes blocks 910-920.

At block 910, a combined signal (e.g., first combined signal PADA or second combined signal PADB in FIG. 2A) is received by a receiving circuitry of a first interface circuitry (e.g., receiving circuitry 224 of side A die 210 or receiving circuitry 264 of side B die 250 in FIG. 2A) from a first terminal of a data lane (e.g., terminal 292a or terminal 292b of data lane 292 in FIG. 2A). In some embodiments, the combined signal is based on a first component signal (e.g., one of TxA or TxB) and a second component (e.g., the other one of TxA or TxB). In some embodiments, the first component signal is output from a transmission circuitry of the first interface circuitry (e.g., transmission circuitry 222 of side A die 210 or transmission circuitry 262 of side B die 250 in FIG. 2A) to the first terminal of the data lane. In some embodiments, the second component signal is from a second interface circuitry (e.g., the other one of TxA or TxB) to a second terminal of the data lane.

At block 920, second data (e.g., one of Data_A or Data_B) from the combined signal is extracted by the receiving circuitry of the first interface circuitry. In some embodiments, the first component signal is based on first data (e.g., the other one of Data_A or Data_B) and from a first output driver of the first interface circuitry, and the second component signal is based on the second data and from a second output driver of the second interface circuitry. In some embodiments, the first output driver is energized by a first supply voltage, and the second output driver is energized by a second supply voltage. In some embodiments, a first supply voltage level (e.g., one of VDDA or VDDB) of the first supply voltage and a second supply voltage level (e.g., the other one of VDDA or VDDB) of the second supply voltage are based on the second supply voltage level being n times the first supply voltage level or the first supply voltage level being n times the second supply voltage level, and n is a real number greater than 1.0. In some embodiments, n is equal to or greater than 1.5. in some embodiments, n ranges from 1.8 to 2.4.

In some embodiments, the first component signal is based on a first data clock signal (e.g., one of CLK_D1 or CLK_D2), and the second component signal is based on a second data clock signal (e.g., the other one of CLK_D1 or CLK_D2), as illustrated based on the examples in FIG. 2A. In some embodiments, method 900 further includes receiving, by the receiving circuitry, a first reference clock signal from a clock lane, the first reference clock signal corresponding to the second data clock signal with a delay. In some embodiments, method 900 further includes extracting, by the receiving circuitry, the second data from the combined signal based on a first triggering clock signal (e.g., CLK_TR1 or CLK_TR2) derived based on the first reference clock signal. In some embodiments, method 900 further includes deriving the first triggering clock signal based on delaying the first reference clock signal by a quarter-phase (e.g., the examples in FIGS. 6A and 6B).

In some embodiments, based on the second supply voltage level (e.g., VDDB) is n times the first supply voltage level (e.g., VDDA), method 900 further includes extracting, by the receiving circuitry, the second data (e.g., Data_B) based on comparing the combined signal (e.g., PADA) against an intermediate reference voltage level (e.g., VREFM). In some embodiments, the intermediate reference voltage level is determined based on (VDDA/4+VDDB/4), VDDA representing the first supply voltage level, and VDDB representing the second supply voltage level.

In some embodiments, based on the first supply voltage level (e.g., VDDB) is n times the second supply voltage level (e.g., VDDA), method 900 further includes extracting, by the receiving circuitry, a first reference data (e.g., reference data VHB) based on comparing the combined signal against a high reference voltage level, extracting, by the receiving circuitry, a second reference data (e.g., reference data V M B) based on comparing the combined signal against an intermediate reference voltage level, and extracting, by the receiving circuitry, a third reference data (e.g., reference data VLB) based on comparing the combined signal against a low reference voltage level. In some embodiments, method 900 further includes decoding, by the receiving circuitry, the second data (e.g., Data_A) based on a logic combination of the first reference data, the second reference data, and the third reference data. In some embodiments, the high reference voltage level is determined based on (VDDA/4+VDDB/2), VDDA representing the first supply voltage level, and VDDB representing the second supply voltage level, the intermediate reference voltage level is determined based on (VDDA/4+VDDB/4), and the low reference voltage level is determined based on VDDA/4.

In some embodiments, the decoding the second data is based on the logic combination of DOUT=DH OR (DM XOR DL), as illustrated in the example of FIG. 5B. Here, DOUT represents a decoded binary value of the second data at a given time, and DH, DM, and DL represent corresponding binary values of the first reference data (e.g., DHB), the second reference data (e.g., DM B), and the third reference data (e.g., DLB) at the given time.

In some embodiments, based on the first supply voltage level (e.g., VDDB) is n times the second supply voltage level (e.g., VDDA), method 900 further includes generating, by the receiving circuitry, the first data clock signal based on a phase of the first reference clock signal, as illustrated based on the example in FIG. 6B.

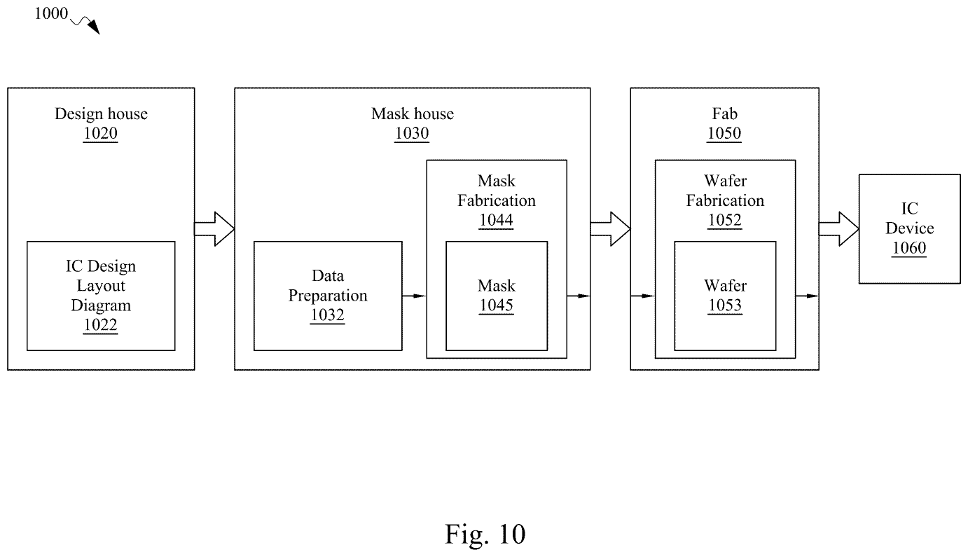

FIG. 10 is a block diagram of an IC manufacturing system 1000, and an IC manufacturing flow associated therewith, in accordance with some embodiments. In some embodiments, based on a layout diagram, at least one of (A) one or more semiconductor masks or (B) at least one component in a layer of a semiconductor integrated circuit (e.g., side A die 210 and/or side B die 250 in FIG. 2A in view of the examples in FIGS. 2B-6B) is fabricated using manufacturing system 1000.

In FIG. 10, IC manufacturing system 1000 includes entities, such as a design house 1020, a mask house 1030, and an IC manufacturer/fabricator (fab) 1050, that interact with one another in the design, development, and manufacturing cycles and/or services related to manufacturing an IC device 1060. The entities in system 1000 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1020, mask house 1030, and IC fab 1050 is owned by a single larger company. In some embodiments, two or more of design house 1020, mask house 1030, and IC fab 1050 coexist in a common facility and use common resources.

Design house (or design team) 1020 generates an IC design layout diagram 1022 (e.g., a layout plan). IC design layout diagram 1022 includes various geometrical patterns designed for an IC device 1060. The geometrical patterns correspond to patterns of metal, oxide, or semiconductor layers that make up the various components of IC device 1060 to be fabricated. The various layers combine to form various IC features. For example, a portion of IC design layout diagram 1022 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1020 implements a proper design procedure to form IC design layout diagram 1022. The design procedure includes one or more of logic design, physical design or place and route. IC design layout diagram 1022 is presented in one or more data files having information of the geometrical patterns. For example, IC design layout diagram 1022 can be expressed in a GDSII file format or DFII file format.

Mask house 1030 includes data preparation 1032 and mask fabrication 1044. M ask house 1030 uses IC design layout diagram 1022 to manufacture one or more masks 1045 to be used for fabricating the various layers of IC device 1060 according to IC design layout diagram 1022. M ask house 1030 performs mask data preparation 1032, where IC design layout diagram 1022 is translated into a representative data file (RDF). M ask data preparation 1032 provides the RDF to mask fabrication 1044. M ask fabrication 1044 includes a mask writer. A mask writer converts the RDF to an image on a substrate, such as a mask (reticle) 1045 or a semiconductor wafer 1053. The design layout diagram 1022 is manipulated by mask data preparation 1032 to comply with particular characteristics of the mask writer and/or requirements of IC fab 1050. In FIG. 10, mask data preparation 1032 and mask fabrication 1044 are illustrated as separate elements. In some embodiments, mask data preparation 1032 and mask fabrication 1044 can be collectively referred to as mask data preparation.

In some embodiments, mask data preparation 1032 includes optical proximity correction (OPC) which uses lithography enhancement techniques to compensate for image errors, such as those that can arise from diffraction, interference, other process effects and the like. OPC adjusts IC design layout diagram 1022. In some embodiments, mask data preparation 1032 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1032 includes a mask rule checker (MRC) that checks the IC design layout diagram 1022 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1022 to compensate for photolithographic implementation effects during mask fabrication 1044, which may undo part of the modifications performed by OPC in order to meet mask creation rules.

In some embodiments, mask data preparation 1032 includes lithography process checking (LPC) that simulates processing that will be implemented by IC fab 1050 to fabricate IC device 1060. LPC simulates this processing based on IC design layout diagram 1022 to create a simulated manufactured device, such as IC device 1060. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (M EEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1022.

It should be understood that the above description of mask data preparation 1032 has been simplified for the purposes of clarity. In some embodiments, data preparation 1032 includes additional features such as a logic operation (LOP) to modify the IC design layout diagram 1022 according to manufacturing rules. Additionally, the processes applied to IC design layout diagram 1022 during data preparation 1032 may be executed in a variety of different orders.

A fter mask data preparation 1032 and during mask fabrication 1044, a mask 1045 or a group of masks 1045 are fabricated based on the modified IC design layout diagram 1022. In some embodiments, mask fabrication 1044 includes performing one or more lithographic exposures based on IC design layout diagram 1022. In some embodiments, an electron-beam (e-beam) or a mechanism of multiple e-beams is used to form a pattern on a mask (photomask or reticle) 1045 based on the modified IC design layout diagram 1022. Mask 1045 can be formed in various technologies. In some embodiments, mask 1045 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1045 includes a transparent substrate (e.g., fused quartz) and an opaque material (e.g., chromium) coated in the opaque regions of the binary mask. In another example, mask 1045 is formed using a phase shift technology. In a phase shift mask (PSM) version of mask 1045, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1044 is used in a variety of processes. For example, such a mask(s) is used in an ion implantation process to form various doped regions in semiconductor wafer 1053, in an etching process to form various etching regions in semiconductor wafer 1053, and/or in other suitable processes.

IC fab 1050 is an IC fabrication business that includes one or more manufacturing facilities for the fabrication of a variety of different IC products. In some embodiments, IC fab 1050 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1050 includes fabrication tools 1052 configured to execute various manufacturing operations on semiconductor wafer 1053 such that IC device 1060 is fabricated in accordance with the mask(s), e.g., mask 1045. In various embodiments, fabrication tools 1052 include one or more of a wafer stepper, an ion implanter, a photoresist coater, a process chamber, e.g., a CVD chamber or LPCVD furnace, a CM P system, a plasma etch system, a wafer cleaning system, or other manufacturing equipment capable of performing one or more suitable manufacturing processes as discussed herein.

IC fab 1050 uses mask(s) 1045 fabricated by mask house 1030 to fabricate IC device 1060. Thus, IC fab 1050 at least indirectly uses IC design layout diagram 1022 to fabricate IC device 1060. In some embodiments, semiconductor wafer 1053 is fabricated by IC fab 1050 using mask(s) 1045 to form IC device 1060. In some embodiments, the IC fabrication includes performing one or more lithographic exposures based at least indirectly on IC design layout diagram 1022. Semiconductor wafer 1053 includes a silicon substrate or other proper substrate having material layers formed thereon. Semiconductor wafer 1053 further includes one or more of various doped regions, dielectric features, multilevel interconnects, and the like (formed at subsequent manufacturing steps).

In some aspects, a communication system includes a data lane based on a first conductive structure, a first transmission circuitry including a first output driver configured to output a first component signal to a first terminal of the data lane, and a second transmission circuitry including a second output driver configured to output a second component signal to a second terminal of the data lane. The first output driver is configured to be energized by a first supply voltage, and the first component signal is based on first data. The second output driver is configured to be energized by a second supply voltage, and the second component signal is based on second data. A second supply voltage level of the second supply voltage is n times a first supply voltage level of the first supply voltage, and n is a real number equal to or greater than 1.5.

In some aspects, a communication method includes receiving, by a receiving circuitry of a first interface circuitry, a combined signal from a first terminal of a data lane, the combined signal being based on a first component signal and a second component signal. The first component signal is from a transmission circuitry of the first interface circuitry to the first terminal of the data lane, and the second component signal is from a second interface circuitry to a second terminal of the data lane. The method further includes extracting, by the receiving circuitry of the first interface circuitry, second data from the combined signal. The first component signal is based on first data and from a first output driver of the first interface circuitry, and the second component signal is based on the second data and from a second output driver of the second interface circuitry. The first output driver is energized by a first supply voltage, and the second output driver is energized by a second supply voltage. A first supply voltage level of the first supply voltage and a second supply voltage level of the second supply voltage are based on the second supply voltage level being n times the first supply voltage level or the first supply voltage level being n times the second supply voltage level, and n is a real number equal to or greater than 1.5.

In some aspects, an interface circuitry includes a transmission circuitry including a first output driver configured to output a first component signal to a first terminal of a data lane, the first output driver being configured to be energized by a first supply voltage, and the first component signal being based on first data. The interface circuitry further includes a receiving circuitry configured to receive a combined signal at the first terminal of the data lane and extract second data from the combined signal. The combined signal is based on the first component signal and a second component signal from a second interface circuitry to a second terminal of the data lane. The second component signal is based on the second data and from a second output driver of the second interface circuitry. The second output driver is configured to be energized by a second supply voltage. A first supply voltage level of the first supply voltage and a second supply voltage level of the second supply voltage are based on the second supply voltage level being n times the first supply voltage level or the first supply voltage level being n times the second supply voltage level, and n is a real number equal to or greater than 1.5.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A communication system, comprising:
a data lane based on a first conductive structure;
a first transmission circuitry including a first output driver configured to output a first component signal to a first terminal of the data lane, the first output driver being configured to be energized by a first supply voltage, and the first component signal being based on first data; and
a second transmission circuitry including a second output driver configured to output a second component signal to a second terminal of the data lane, the second output driver being configured to be energized by a second supply voltage, and the second component signal being based on second data,
wherein
a second supply voltage level of the second supply voltage is n times a first supply voltage level of the first supply voltage, and
n is a real number equal to or greater than 1.5.

2. The communication system of claim 1, further comprising:
a first receiving circuitry configured to receive a first combined signal at the first terminal of the data lane and to extract the second data from the first combined signal.

3. The communication system of claim 2, further comprising:
a first clock lane based on a second conductive structure,
wherein
the first component signal is based on a first data clock signal,
the second component signal is based on a second data clock signal,
the first receiving circuitry is configured to receive a first reference clock signal from the first clock lane, the first reference clock signal corresponding to the second data clock signal with a delay, and
the first receiving circuitry is configured to extract the second data from the first combined signal based on a first triggering clock signal derived based on the first reference clock signal.

4. The communication system of claim 3, wherein
the first triggering clock signal is derived based on delaying the first reference clock signal by a quarter-phase.

5. The communication system of claim 2, wherein
the first receiving circuitry is configured to extract the second data based on comparing the first combined signal against an intermediate reference voltage level, and
the intermediate reference voltage level is determined based on (VDDA/4+VDDB/4), VDDA representing the first supply voltage level, and VDDB representing the second supply voltage level.

6. The communication system of claim 1, further comprising:
a second receiving circuitry configured to receive a second combined signal at the second terminal of the data lane and to extract the first data from the second combined signal.

7. The communication system of claim 6, further comprising:
a second clock lane based on a third conductive structure,
wherein
the first component signal is based on a first data clock signal,
the second component signal is based on a second data clock signal,
the second receiving circuitry is configured to receive a second reference clock signal from the second clock lane, the second reference clock signal corresponding to the first data clock signal with a delay, and
the second receiving circuitry is configured to extract the first data from the second combined signal based on a second triggering clock signal derived based on the second reference clock signal.

8. The communication system of claim 7, wherein
the second triggering clock signal is derived based on delaying the second reference clock signal by a quarter-phase.

9. The communication system of claim 7, wherein
the second receiving circuitry is further configured to generate the second data clock signal based on a phase of the second reference clock signal.

10. The communication system of claim 6, wherein
the second receiving circuitry is configured to:
extract a first reference data based on comparing the second combined signal against a high reference voltage level;
extract a second reference data based on comparing the second combined signal against an intermediate reference voltage level;
extract a third reference data based on comparing the second combined signal against a low reference voltage level; and
decode the first data based on a logic combination of the first reference data, the second reference data, and the third reference data,
the high reference voltage level is determined based on (VDDA/4+VDDB/2), VDDA representing the second supply voltage level, and VDDB representing the first supply voltage level,
the intermediate reference voltage level is determined based on (VDDA/4+VDDB/4), and
the low reference voltage level is determined based on VDDA/4.

11. The communication system of claim 10, wherein
the first data is decoded based on the logic combination of DOUT=DH OR (DM XOR DL),
DOUT represents a decoded binary value of the first data at a given time, and
DH, DM, and DL represent corresponding binary values of the first reference data, the second reference data, and the third reference data at the given time.

12. The communication system of claim 1, wherein
n ranges from 1.8 to 2.4.

13. A communication method, comprising:
receiving, by a receiving circuitry of a first interface circuitry, a combined signal from a first terminal of a data lane, the combined signal being based on a first component signal and a second component signal, the first component signal being from a transmission circuitry of the first interface circuitry to the first terminal of the data lane, and the second component signal being from a second interface circuitry to a second terminal of the data lane; and
extracting, by the receiving circuitry of the first interface circuitry, second data from the combined signal,
wherein
the first component signal is based on first data and from a first output driver of the first interface circuitry,
the second component signal is based on the second data and from a second output driver of the second interface circuitry,
the first output driver is energized by a first supply voltage,
the second output driver is energized by a second supply voltage,
a first supply voltage level of the first supply voltage and a second supply voltage level of the second supply voltage are based on the second supply voltage level being n times the first supply voltage level or the first supply voltage level being n times the second supply voltage level, and
n is a real number equal to or greater than 1.5.

14. The communication method of claim 13, wherein
the first component signal is based on a first data clock signal,
the second component signal is based on a second data clock signal, and
the method further comprises:
receiving, by the receiving circuitry, a first reference clock signal from a clock lane, the first reference clock signal corresponding to the second data clock signal with a delay, and
extracting, by the receiving circuitry, the second data from the combined signal based on a first triggering clock signal derived based on the first reference clock signal.

15. The communication method of claim 14, further comprising:
deriving the first triggering clock signal based on delaying the first reference clock signal by a quarter-phase.

16. The communication method of claim 14, further comprising, based on the second supply voltage level is n times the first supply voltage level:
extracting, by the receiving circuitry, the second data based on comparing the combined signal against an intermediate reference voltage level,
wherein
the intermediate reference voltage level is determined based on (VDDA/4+VDDB/4), VDDA representing the first supply voltage level, and VDDB representing the second supply voltage level.

17. The communication method of claim 14, further comprising, based on the first supply voltage level is n times the second supply voltage level:
extracting, by the receiving circuitry, a first reference data based on comparing the combined signal against a high reference voltage level;
extracting, by the receiving circuitry, a second reference data based on comparing the combined signal against an intermediate reference voltage level;
extracting, by the receiving circuitry, a third reference data based on comparing the combined signal against a low reference voltage level; and
decoding, by the receiving circuitry, the second data based on a logic combination of the first reference data, the second reference data, and the third reference data,
wherein
the high reference voltage level is determined based on (VDDA/4+VDDB/2), VDDA representing the second supply voltage level, and VDDB representing the first supply voltage level,
the intermediate reference voltage level is determined based on (VDDA/4+VDDB/4), and
the low reference voltage level is determined based on VDDA/4.

18. The communication method of claim 14, further comprising, based on the first supply voltage level is n times the second supply voltage level:
generating, by the receiving circuitry, the first data clock signal based on a phase of the first reference clock signal.

19. An interface circuitry, comprising:
a transmission circuitry including a first output driver configured to output a first component signal to a first terminal of a data lane, the first output driver being configured to be energized by a first supply voltage, and the first component signal being based on first data; and
a receiving circuitry configured to
receive a combined signal at the first terminal of the data lane, the combined signal being based on the first component signal and a second component signal from a second interface circuitry to a second terminal of the data lane, and
extract second data from the combined signal,
wherein
the second component signal is based on the second data,
the second component signal is from a second output driver of the second interface circuitry,
the second output driver is configured to be energized by a second supply voltage,
a first supply voltage level of the first supply voltage and a second supply voltage level of the second supply voltage are based on the second supply voltage level being n times the first supply voltage level or the first supply voltage level being n times the second supply voltage level, and
n is a real number equal to or greater than 1.5.

20. The interface circuitry of claim 19, wherein
the first component signal is based on a first data clock signal,
the second component signal is based on a second data clock signal, and
the receiving circuitry is further configured to:
receive a first reference clock signal from a clock lane, the first reference clock signal corresponding to the second data clock signal with a delay, and
extract the second data from the combined signal based on a first triggering clock signal derived based on the first reference clock signal.
